(19) United States
(12) Patent Application Publication
(10) Pub. No.: US 2016/0073548 A1
(43) Pub. Date: Mar. 10, 2016

(54) COOLING MODULE, COOLING MODULE MOUNTING BOARD AND ELECTRONIC DEVICE

(71) Applicant: FUJITSU LIMITED, Kawasaki-shi (JP)

(72) Inventors: JIE WEI, Hachioji (JP); keizou Takemura, Kawasaki (JP)

(21) Appl. No.: 14/790,628

(22) Filed: Jul. 2, 2015

(30) Foreign Application Priority Data
Sep. 4, 2014 (JP) 2014-180057

(51) Int. Cl. H05K 7/20

(52) U.S. Cl. CPC H05K 7/2029; H05K 7/20409

(57) ABSTRACT

A cooling module includes a casing that stores a heating element and a coolant in which the heating element is immersed; and a liquid channel through which a cooling liquid that condenses vapor of the coolant in an upper portion of the casing flows.

### CROSS-REFERENCE TO RELATED APPLICATION

This application is based upon and claims the benefit of priority of the prior Japanese Patent Application No. 2014-180057, filed on Sep. 4, 2014, the entire contents of which are incorporated herein by reference.

### FIELD

The embodiment discussed herein is related to for example, a cooling module, a cooling module mounting board, and an electronic device.

### BACKGROUND

Performance of electronic devices is becoming increasingly higher. Thus, various techniques have been proposed in recent years, which effectively cool electronic components that generate an increased amount of heat with the growth in the performance of the electronic devices. For example, Japanese Laid-open Patent Publication No. 10-209356, Japanese Laid-open Patent Publication No. 2005-72542, and Japanese National Publication of International Patent Application No. 2011-530195 are disclosed as related art.

### SUMMARY

In accordance with an aspect of the embodiments, a cooling module includes a casing that stores a heating element and a coolant in which the heating element is immersed; and a liquid channel through which a cooling liquid that condenses vapor of the coolant in an upper portion of the casing flows.

The object and advantages of the invention will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

These and/or other aspects and advantages will become apparent and more readily appreciated from the following description of the embodiments, taken in conjunction with the accompanying drawing of which:

FIG. 1 illustrates an example of a cooling module according to an embodiment;

FIG. 2 illustrates an example of a cooling module mounting board where the cooling module is mounted over a printed board;

FIG. 3 illustrates an example of a structural diagram of a fine structure element and a heating element;

FIG. 4 illustrates an example of a circulation state of a coolant in the cooling module;

FIG. 5 illustrates an example of a cooling module mounting board where a cooling module according to a comparison example is mounted over a printed board; and

FIGS. 6A and 6B illustrate examples of electronic devices in which the cooling modules are provided.

### DESCRIPTION OF EMBODIMENT

An embodiment is described below. The embodiment described below is merely an exemplification and is not intended to limit the technical scope of the present disclosure to the below-described aspects.

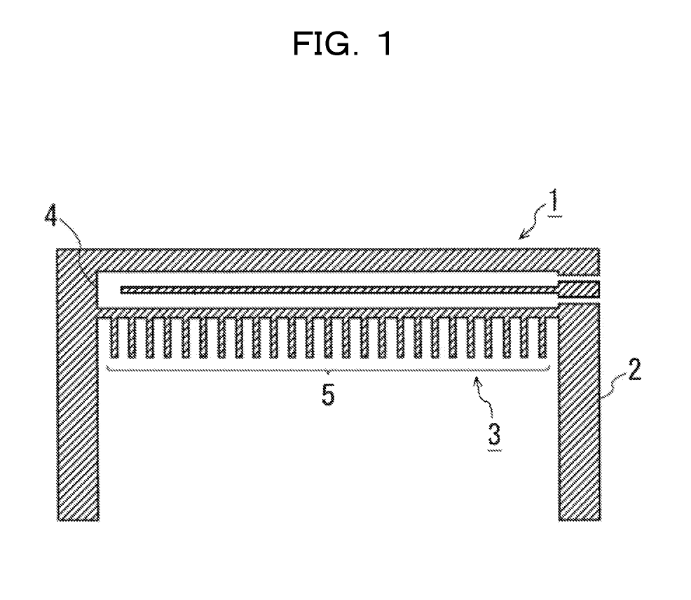

FIG. 1 illustrates an example of a cooling module 1 according to the embodiment. The cooling module 1 includes a casing 2. The casing 2 has a square-shaped appearance and is opened on the lower side. Accordingly, the casing 2 may be mounted over a printed board where various heating elements are arranged, such as large scale integration (LSI), so as to cover the heating elements.

The cooling module 1 includes a liquid channel 4 formed on the back side of a ceiling surface 3 of the casing 2. The liquid channel 4 is a channel through which a cooling liquid for condensing vapor of a coolant in which a heating element is immersed flows. Fins 5 are formed on the ceiling surface 3 in the casing 2 so that the vapor of the coolant in the casing 2 may be easily condensed. The fins 5 are formed for the purpose of increasing a heat transmission area of the cold of the liquid that flows through the liquid channel 4. Although FIG. 1 exemplifies the cooling module 1 where the liquid channel 4 is formed in an upper portion in the casing 2, the liquid channel 4 may have any other form as long as the form enables the vapor of the coolant to be condensed in the upper portion of the casing 2. For example, even when the liquid channel 4 is formed inside a casing that is different from the casing 2 and placed over the casing 2 or even when a tube fixed to an upper surface of the casing 2 forms the liquid channel 4, the vapor of the coolant in the casing 2 may be condensed in the upper portion of the casing 2.

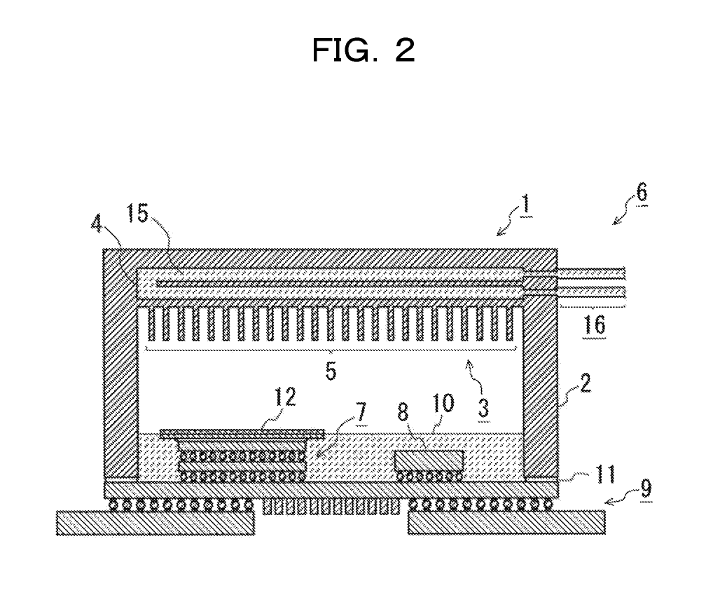

FIG. 2 illustrates an example of a cooling module mounting board 6 where the cooling module 1 is mounted over a printed board 9. The cooling module mounting board 6 includes the printed board 9 where various kinds of heating elements, which are heating elements 7 and 8, and the cooling module 1 mounted over the printed board 9. The heating elements 7 and 8, and a coolant 10 are stored in the casing 2 of the cooling module 1. The casing 2 is joined to the printed board 9 using a joining material 11 without causing any gap so as to avoid the coolant 10 stored in the casing 2 from leaking to the outside. The casing 2 stores the heating elements 7 and 8 in a lower portion in the casing 2. Accordingly, as illustrated in FIG. 2, the heating elements 7 and 8 stored in the lower portion in the casing 2 enter a state in which the heating elements 7 and 8 are immersed in the coolant 10 stored in the casing 2. A tube 16 that allows a liquid 15 to flow through the liquid channel 4 is connected to an inlet and an outlet of the liquid channel 4.

The coolant 10 is preferably an inert liquid that does not erode the heating elements 7 and 8, the printed board 9, or the casing 2. Examples of the inert liquid include “Fluorinert” available from 3M Company, which is a fluorine-based inert liquid. Preferably, the coolant 10 evaporates with the heat of the heating elements 7 and 8 and condenses with the cold of the liquid that flows through the liquid channel 4. The coolant 10 to be stored in the casing 2 may be selected as desired according to the amount of the heat that the heating elements 7 and 8 cause, the heat-resistant temperatures of the heating elements 7 and 8, the flow rate or temperature of the liquid that flows through the liquid channel 4, the surface areas of the fins 5, the material of the casing 2, the volume of a space in the casing 2, or various other factors.

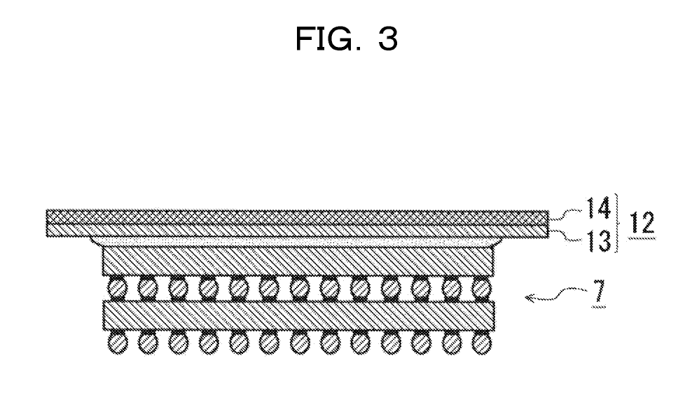

The heating element 7 of the two heating elements 7 and 8 generates the greater amount of heat and includes a fine structure element 12 attached to an upper surface of the heating element 7. The expression “fine” used herein means “very small” or “minute”. FIG. 3 illustrates an example of a structural diagram of the fine structure element 12 and the heating element 7. The fine structure element 12 is a plate-like member with a surface larger than the upper surface of the heating element 7 and is immersed in the coolant 10. The fine structure element 12 includes a substrate 13 and a fine structure 14 that covers an upper surface of the substrate 13, and the heating element 7 is joined to a lower surface of the substrate 13. A large number of fine bores are formed in the fine structure 14, which enable the coolant 10 to be retained. While there are various kinds for a typical material that may be impregnated with a liquid, it is preferable that the heat of the heating element 7 is effectively transmitted all over the fine structure 14 so as to achieve effective boiling and evaporation of the coolant 10. An example of a material that has favorable ability in heat transmission and allows such fine bores to be formed is silicon. Silicon enables various kinds of fine structure elements to be formed through the application of a semiconductor manufacturing process. When the fine structure element 12 is made of silicon and the heating element 7 is LSI, the fine structure element 12 may be attached to a surface of the LSI by bringing various metal joining techniques or welding techniques into full use. The fine structure element 12 that may be impregnated with the coolant 10 maintains a state in which the surface of the heating element 7 is immersed in the coolant 10 so as to avoid the surface of the heating element 7 from drying and then decreasing in cooling effect. Since latent heat desired when a substance changes from a liquid phase to a gaseous phase is large, the heating element 7 may be effectively cooled when the surface of the heating element 7 is immersed in the coolant 10.

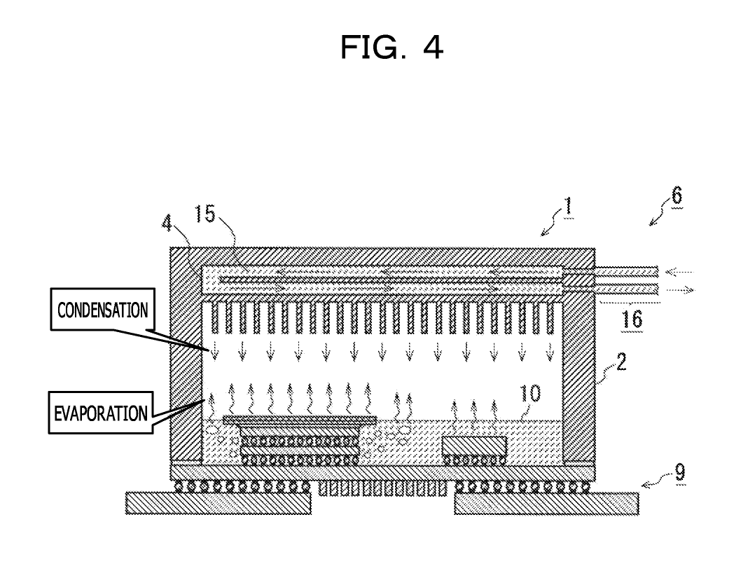

FIG. 4 illustrates an example of a circulation state of the coolant 10 in the cooling module 1. When the heating elements 7 and 8 generate heat, the coolant 10 in the liquid phase, where the heating elements 7 and 8 are immersed, is heated. When the temperature of the coolant 10 exceeds a boiling point, the coolant 10 boils and evaporates. The coolant 10 in the gaseous phase, which has evaporated, comes into contact with the fins 5 formed on the ceiling surface 3 in the casing 2 and is cooled by the cold of the liquid 15 that flows in the liquid channel 4. The coolant 10 in the gaseous phase, which has been cooled by the cold of the liquid 15, condenses on the surfaces of the fins 5. The coolant 10 in the liquid phase, which has condensed on the surfaces of the fins 5, falls from the fins 5 as drops. The heating elements 7 and 8 are immersed in the coolant 10 that has fallen from the fins 5 as drops and the coolant 10 boils and evaporates again. The heat of the heating elements 7 and 8 is effectively transmitted to the liquid 15 in the liquid channel 4 by the coolant 10 repeating the evaporation and the condensation inside the casing 2. The latent heat at the time when a substance involves change in phase is larger in thermal energy than sensible heat. Accordingly, further downsizing or increase in performance of an electronic device may be achieved by implementing cooling techniques that utilize the latent heat using the above-described cooling module 1.

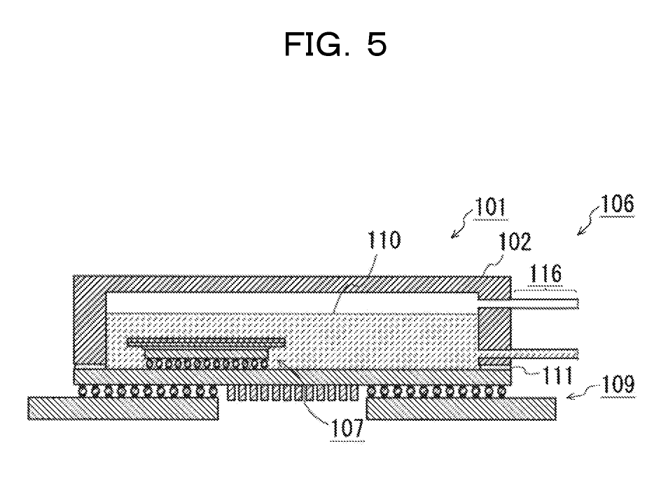

FIG. 5 illustrates an example of a cooling module mounting board 106 where a cooling module 101 according to a comparison example is mounted over a printed board 109. The cooling module mounting board 106 includes the printed board 109 where a heating element 107 of some kind is arranged, and the cooling module 101 mounted over the printed board 109. The cooling module 101 according to the comparison example includes a casing 102 with a square-shaped appearance. The casing 102 is joined to the printed board 109 using a joining material 111 without causing any gap so as to cover the heating element 107 over the printed board 109. A coolant 110 is stored in the casing 102. The coolant 110 circulates inside and outside the casing 102 by flowing into the casing 102 in a liquid state from an inlet of a tube 116 connected to the casing 102 and flowing out from an outlet of the tube 116 in a gaseous state after being vaporized in the casing 102.

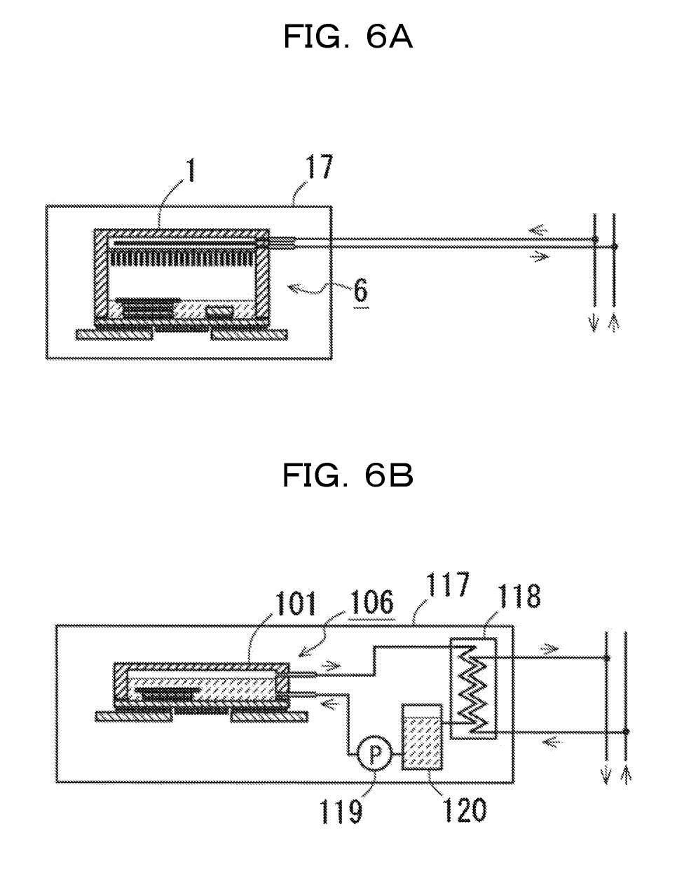

FIGS. 6A and 6B illustrate examples of electronic devices 17 and 117 in which the cooling modules 1 and 101 are provided, respectively. The electronic device 17 to which the cooling module 1 according to the embodiment is applied is depicted in FIG. 6A while the electronic device 117 to which the cooling module 101 according to the comparison example is applied is depicted in FIG. 6B. When the cooling module 1 according to the embodiment is applied to the electronic device 17, for example, cooling water of cooling water supply equipment for air conditioning of a building or for various other purposes may be guided into the electronic device 17 and the guided cooling water may flow through the liquid channel 4 of the cooling module 1. When the cooling module 101 according to the comparison example is applied to the electronic device 117, directly guiding the cooling water of the cooling water supply equipment for air conditioning of a building or for various other purposes into the cooling module 101 is impossible and thus, it is desired to provide the inside of the electronic device 117 with a heat exchanger 118 that causes the coolant 110 vaporized in the cooling module mounting board 106 to condense and a coolant circulating pump 119 that sends the coolant 110 after the condensation in the liquid phase to the cooling module mounting board 106. It is further desired to provide the drawing side of the coolant circulating pump 119 with a tank 120 that temporarily retains the coolant 110 in the liquid phase after the condensation by the heat exchanger 118. That is, as the contrast between the electronic device 17 depicted in FIG. 6A and the electronic device 117 depicted in FIG. 6B indicates, it is found that the application of the cooling module 1 according to the embodiment may simplify the configuration in the electronic device, compared to the case in which the cooling module 101 according to the comparison example is applied.

In the above-described cooling module 1 according to the above-described embodiment, the casing 2 is not limited to the square-shaped casing. The form or size of the casing 2 may be changed according to the form of the printed board 9 where the casing 2 is mounted, the positions, sizes, or forms of the heating elements 7 and 8, and the like. In addition, the cooling module 1 according to the above-described embodiment is not limited to the cooling module where the fins 5 are provided inside the casing 2. When the ceiling surface 3 in the casing 2 includes a sufficient heat exchange area, the fins 5 may be omitted. Further, the cooling module 1 according to the above-described embodiment is not limited to the cooling module that stores the heating element 7 to which the fine structure element 12 is attached. The cooling module 1 may simply store a heating element to which the fine structure element 12 is not attached, or may simply store a heating element to which the fine structure element 12 is attached.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A cooling module comprising:
a casing that stores a heating element and a coolant in which the heating element is immersed; and
a liquid channel through which a cooling liquid that condenses vapor of the coolant in an upper portion of the casing flows.

2. The cooling module according to claim 1,
wherein a fin that allows the vapor of the coolant to be condensed using cold of the liquid flowing through the liquid channel is formed on a ceiling surface of the casing.

3. The cooling module according to claim 1,
wherein the liquid channel is formed on a back side of a ceiling surface of the casing.

4. The cooling module according to claim 1,
wherein the casing stores the heating element in a lower portion of the casing.

5. The cooling module according to claim 1,
wherein the casing stores the heating element with a surface on which a fine structure impregnated with the coolant is provided.

6. A cooling module mounting board comprising:
a printed board where a heating element is arranged; and
a cooling module mounted over the printed board, the cooling module including
a casing that stores the heating element and a coolant in which the heating element is immersed, and
a liquid channel through which a cooling liquid that condenses vapor of the coolant in an upper portion of the casing flows.

7. The cooling module mounting board according to claim 6,
wherein a fin that allows the vapor of the coolant to be condensed using cold of the liquid flowing through the liquid channel is formed on a ceiling surface of the casing.

8. The cooling module mounting board according to claim 6,
wherein the liquid channel is formed on a back side of a ceiling surface of the casing.

9. The cooling module mounting board according to claim 6,
wherein the casing stores the heating element in a lower portion of the casing.

10. The cooling module mounting board according to claim 6,
wherein the casing stores the heating element with a surface on which a fine structure impregnated with the coolant is provided.

11. An electronic device comprising:
a printed board where a heating element is arranged; and
a cooling module mounted over the printed board, the cooling module including
a casing that stores the heating element and a coolant in which the heating element is immersed, and
a liquid channel through which a cooling liquid that condenses vapor of the coolant in an upper portion of the casing flows.

12. The electronic device according to claim 11,
wherein a fin that allows the vapor of the coolant to be condensed using cold of the liquid flowing through the liquid channel is formed on a ceiling surface of the casing.

13. The electronic device according to claim 11,
wherein the liquid channel is formed on a back side of a ceiling surface of the casing.

14. The electronic device according to claim 11,
wherein the casing stores the heating element in a lower portion of the casing.

15. The electronic device according to claim 11,
wherein the casing stores the heating element with a surface on which a fine structure impregnated with the coolant is provided.
